(19) United States
(12) Patent Application Publication
(10) Pub. No.: US 2008/0248214 A1
(43) Pub. Date: Oct. 9, 2008

(54) METHOD OF FORMING AN OXIDE COATING WITH DIMPLES ON ITS SURFACE

(76) Inventors: Xueyuan Nie, Windsor (CA); Jingzeng Zhang, Windsor (CA)

Correspondence Address: Xueyuan Nie, 2844 California Ave, Windsor, ON, N9E 3W9, CA

(21) Appl. No.: 11/733,013

(22) Filed: Apr. 9, 2007

(51) Int. Cl. C23C 14/02

(52) U.S. Cl. 427/534

(57) ABSTRACT

This invention involves a process of forming an oxide coating with dimples on Al, Mg and Ti alloys. The oxide coating with dimples on its surface is produced by the process consisting of an electrochemical etching on the surface of those alloys followed by plasma oxidation in an alkaline electrolytic solution using a high voltage power supply. The as-prepared coating has smooth surface finish and improved properties being suitable for wear and corrosion protection of materials which have contacts with each other. The present invention can also be applied onto Al—Si and Mg alloys for wear and corrosion-wear prevention of sleeveless aluminium and magnesium engines.

### TECHNICAL FIELD

This invention relates to a process dealing with surface modification of aluminium, aluminium-silicon, magnesium, and titanium alloys for wear and corrosion prevention.

### BACKGROUND OF THE INVENTION

Being lightweight will improve fuel efficiency and reduce emission of vehicles, so using Al, Mg, and Ti alloys as weight-saving materials has become increasingly important in the automotive and aerospace industries. Al and Mg sheets and extrusions have been found more and more applications in the transportation vehicles. Cast Al—Si alloys and Mg alloys have been or will be used in powertrain applications as lightweight components. There is a trend of development of Al and Mg sleeveless engines to further reduce vehicle weight. However, the sliding wear problem on the Al and Mg cylinder bores has to be dissolved before sleeveless Al and Mg engines are in use. There is another trend in usage of alternative fuels, for instances, biofuels such as E85, 85% ethanol and 15% gasoline, due to the pressure of shortage of fossil fuels. Unfortunately, the ethanol is corrosive to Al—Si alloys and Mg alloys. Thick Cr-based, Ni-based, and oxide coatings may be some of the solutions, but those coating processes need pro-surface preparation and post-surface finish, i.e., honing and cross-hatching, which results in an extra cost. Many coating processes have been eliminated from automotive applications due to the increased process cost. The potential environmental pollution caused by the coating processes is also concerned.

Al and Mg parts usually suffer from corrosion problems, including general corrosion and galvanic corrosion caused by corrosive environment, deicing salts, and coolants. Joining of those materials by welding, bolting, riveting, and adhesive bonding is subjected to galvanic corrosion.

Since the wear and corrosion occur on the material surface and the auto parts industry is being pressured by the increasing price of materials and automakers seeking to reduce costs, there is a need to develop a new cost-effective surface treatment process which can produce a wear- and corrosion-resistant coating without costly pro- and post-treatments required. In this invention, a thin oxide coating with numerous dimples on its surface is prepared on a component made of an Al, Mg, Ti, or Al—Si alloy. The oxide layer has a thickness of usually 0.5 to 5 microns with a surface roughness R.sub.a of less than 0.6 micron. No complicated post-treatment, polishing, honing, and cross-hatching are needed for the final surface finish.

The invented process is carried out in an environmentally-friendly alkaline aqueous solution at a high voltage, different from the conventional and hard anodizing which usually proceeds in acidic and fluoride solutions at a few tens of volts of electrode voltage as used in Patent No.: U.S. Pat. No. 5,884,600, U.S. Pat. No. 4,801,360 and CA 2,462,764. In the conventional and hard anodizing processes, some element, for instance Cu and Si in an Al or Al—Si alloy, cannot be anodized. The anodized surface can not be completely covered with the oxide coating. There is no metallurgical integration at the boundary interfaces between its precipitates and metallic matrix.

The processes in the prior art, as described in patents Patent No.: U.S. Pat. No. 6,808,613, U.S. Pat. No. 6,896,785, WO03083181, U.S. Pat. No. 6,365,028, and U.S. Pat. No. 5,616,229, intended to produce a very thick oxide coating, coating thickness: 50 to 300 microns, that usually has a very rough surface. A complicated grinding, polishing or honing post-process is necessary if the coating is used for tribological applications. The thick coating also has a very low thermal conductivity and a high hardness up to 20 GPa. Such a high hardness usually causes severe wear to counterface materials during a sliding contact. In addition, the processing time for the thick coating usually is very long, lasting 1 to 2 hours. A huge power supply, hundreds of kilowatts, is needed for the treatment. Those make the process expensive, limiting its general applications in corrosion prevention.

Unlike the thick oxide coating, the as-prepared thin coating in this invention has a smooth surface finish, hardness of 3 to 10 GPa, and high thermal conductivity similar to a metal. Thus, no complicated post-surface finishing, grinding, and honing are necessary for the coated surface, which significantly reduce the manufacturing cost. The oxide coating has a great number of dimples on its surface. Such dimples function as oil reservoirs for reduction of friction. The relatively soft oxide coating will cause a little wear to the counterface materials. The thin coating has a dense ceramic underlayer which can provide corrosion protection to cast components, sheets, and extrusions made of Al, Mg, and Ti alloys.

### SUMMARY OF THE INVENTION

This invention involves a process of forming a thin oxide coating with dimples on the coating surface. The coating with dimples on its surface is prepared using an AC, DC or pulse DC power in an alkaline electrolyte which contacts, by spraying or immersing, components made of lightweight Al, Al—Si, Mg, and Ti alloys. The oxide coating layer has a thickness of 0.5 to 5 microns with a hardness of 3 to 10 GPa measured by nanoindentation. The coating surface has an arithmetic mean average surface roughness, R.sub.a, of less than 0.6 microns and a thermal conductivity similar to a metal. After the process, no complicated post-treatment, honing and cross-hatching are needed for the coating applications.

The invented process can be described as the following steps:

Step 1. A surface of an Al, Mg, Ti, or Al—Si alloy, which consists of a corresponding metallic matrix and hard precipitates, is electrochemically etched first by an alkaline solution, pH 10 to 12, in which the alloy, as an anode, is connected with a high voltage power supply. As a result, the metallic matrix surface of Al, Mg, Ti, or Al—Si alloy is etched down by 0.3 to 3 microns, and the hard precipitates in the matrix protrude from the surface with the exposed peak height up to 3 microns.

Step 2. The etched metallic matrix surface then grows with the formation of a thin oxide layer by plasma oxidation when the applied voltage increases, making the surface smoother. The surface consists of corresponding metal-containing oxides on the metallic matrix areas and precipitating element-containing oxides in the grain boundary regions of the precipitates where metallurgical-bonding interfaces between the metallic matrix and grains of the precipitates are established. With the increase of the oxide layer thickness, the regions at hard precipitates will also perform plasma oxidation, forming oxides on their surfaces. The oxide coating layer thickness can be in the range of 0.5 to 5 microns and the surface roughness R.sub.a less than 0.6 micron. The dielectric plasma discharges on the oxide surface are utilized to produce a number of surface dimples with a size of 0.5 to 5 microns in diameter. The coverage of the dimples is more than 5,000 dimples per square millimeter. Such dimples can be used as oil reservoirs facilitating distribution of the oil lubricants for tribological applications.

Step 3. With the increase in treatment time, the entire surface is completely covered with the oxide ceramic coating with the layer thickness of 6 to 10 microns. The surface finish gradually becomes rougher in this step, but its surface roughness is still less than 1.5 microns. During the whole process lasting about 5 to 10 minutes, the coating surface changes from a slight rough surface formed through the etching in Step 1 to a smooth surface due to coating growth and compensation in Step 2 and then to a relatively rough surface again in Step 3.

Usually, the process should terminate at Step 2 in which the oxide layer with dimples on its surface has a thickness of 0.5 to 5 microns, and the surface roughness is less than 0.6 microns. There is no need for any post-treatments, polishing, honing, and cross-hatching, which reduces the manufacturing cost.

If the process ends at Step 3, the oxide layer thickness is in the range of 6 to 10 microns and surface roughness R.sub.a 0.8 to 1.5 microns. Although a slight surface polishing is usually suggested to make the surface finish from R.sub.a 0.8 to 1.5 microns to R.sub.a 0.3 to 0.5 micron for a tribological application, no grinding, honing, and crosshatching process are required, which can still significantly reduce the manufacturing cost.

The thin oxide coating formed on an Al—Si alloy can be applied on a sleeveless Al engine bore and piston for protection from mild and severe engine wear.

The thin oxide coating formed on an Mg alloy can be applied on a sleeveless Mg engine bore and piston for battling mild and severe engine wear.

The thin oxide coating has a dense ceramic underlayer which can provide corrosion prevention for Al, Mg, and Ti alloys.

### BRIEF DESCRIPTION OF THE DRAWINGS

The invention will better be understood when considered in the light of the following detailed description of a specific embodiment thereof which is given hereafter in conjunction with the drawings in which:

FIG. 1 is a sectioned side view of an engine cylinder bore and surrounding block which is used as a model system showing how to treat an interior surface;

FIG. 2 is a sectioned side view of a piston which is used as a model system showing how to treat an exterior surface; and

FIG. 3 is a sectioned side view of an alloy and coating, schematically showing the process of electrochemical etching and the coating growth by plasma oxidation.

### DETAILED DESCRIPTION OF THE PREFERRED EMBODIMENT OF THE INVENTION

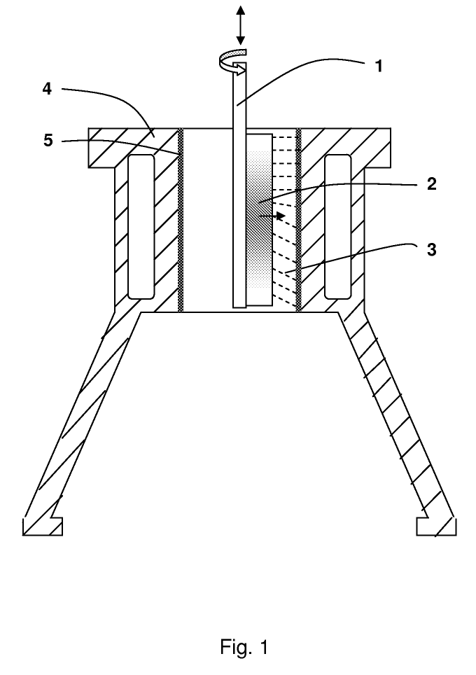

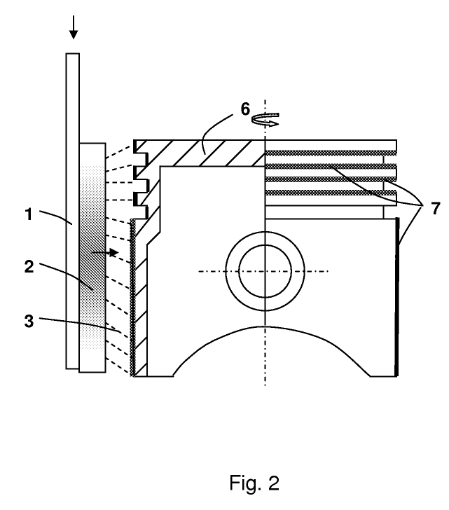

As illustrated in FIG. 1, a rotating hollow shaft 1 with one to four perforated spraying heads 2 sprays an electrolytic solution 3 onto an interior surface, for instance, a cylinder or engine block 4 bore 5. For a plurality of cylinders or bores 5, a multiple of the above spraying head system 1+2 may be required. In said process, for a V8 engine which has eight cylinder bores, eight above systems may be needed. The treated cylinder bores 4+5 and the spraying head systems 1+2 are respectively connected to a positive and negative output of a high voltage power supply. The applied voltage is in excess of 150V.

As illustrated in FIG. 2, a fixed hollow shaft 1 with a perforated spraying head 2 sprays an electrolytic solution 3 onto an exterior surface, for instance, a piston 6 and piston surface 7 that can be fixed, rotating, or moving. The treated piston 6 and the spraying head system 1+2 are respectively connected to a positive and negative output of a high voltage power supply. The applied voltage is in excess of 150V. The spraying head can be held and maneuvered by an automated robotic system for the localized surface treatment on large sheets, extrusions, and cast components as well as on the areas of welding, bolting, riveting, and adhesive bonding.

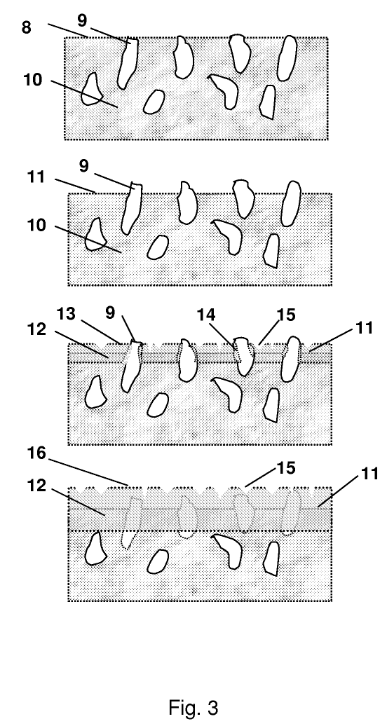

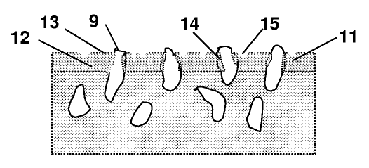

An oxide coating will form on the interior surface, for instance cylinder and engine bore, and the exterior surfaces, for instance piston, as schematically shown in FIG. 3. The cylinder bore and piston are made of Al, Al—Si, Mg or Ti alloy comprising of precipitation grains distributed in the corresponding metal matrix. Using an Al—Si alloy as an example, hard primary precipitates in the alloy is Si grains, and the soft metallic matrix is Al.

As shown in FIG. 3, the said alloy is connected to a DC, AC, or pulse DC power supply during the treatment in FIG. 1 or FIG. 2. The treatment process starts with a slight etching procedure wherein the original surface 8 of any of said alloys is etched to some extent. Taking an Al—Si alloy as an example, the invented process is described as follows.

During the etching process, the primary Si grains 9 are exposed from the aluminum matrix 10, and a new surface 11 forms. The surface finish after treatment is in a range of R.sub.a 0.3 to 1.0 micron, as stated above in Step 1.

Then, a thin oxide coating 12 is grown, by plasma oxidation, on the etched Al—Si alloy surface 11. The coating has a thickness of 0.5 to 5 microns, and a new coated surface 13 forms. The new coated surface 13 consists of a thin Al oxide coating 12 surface and exposed Si grain 9 surfaces with Si—O oxides 14 metallurgically bonding the Si grains and Al matrix at their boundary areas. A great number of dimples 15, generated by dielectric discharges of the oxide layer, are formed on all of the oxide surface areas. The thickness of the outward-grown part of the oxide layer from the etched surface 11 is in a range of one-third to half of the total coating thickness. The grown oxide layer compensates for the dimension reduction caused by the etching step in Step 1, resulting in a less final dimension change at this stage, as stated above in Step 2. The coated surface has more than 5,000 dimples in each square millimeter area and the dimple size is in range of 0.5 to 5 microns in diameter. The treated surface possesses a hardness of 3 to 10 GPa, protecting the soft metallic matrix from scratching.

With the increase in the treatment time, the coating 12 thickness increases. The thickened oxide coating eventually covers the whole surface 16 without any exposition of Si grains. The entire surface 16 on the Al—Si alloy is finally covered with an Al—Si—O oxide coating with a thickness of 6 to 10 microns, as stated above in Step 3. The coating surface roughness is in the range of R.sub.a 0.8 to 1.5 microns.

In general terms, the oxide coating with numerous dimples on its surface is thus formed on an Al, Al—Si, Mg or Ti alloy. The dimples have a size of 0.5-5 microns in diameter and can be favorably utilized as reservoirs of oil lubricants for reduction of friction and shear force generated during sliding contact. Metallurgical bonding also forms between the metal matrix and hard precipitates. Such a strong bonding is critical to avoid breaking and delaminating of the hard precipitates from the soft metal matrix during the sliding wear.

In addition, the oxide layer on the said Al, Al—Si, Mg and Ti alloy eliminates metal-to-metal sliding contact and can withstand a higher heat impact than the said bare alloy itself, which increases resistance to adhesive and scuffing wear. The coating also has a thermal conductivity similar to a metal. The improved heat conductivity reduces the cylinder bore distortion if the coating is applied on Al and Mg engine bores. The coated surface has a ceramic layer on the top of the metals, providing protection from general and galvanic corrosion.

The as-prepared thin coating has an enhanced metallurgical, tribological, thermal, and anti-corrosive property, and a smooth surface finish as well as a little dimension change, therefore post-treatments, polishing, honing, and cross-hatching after the coating process are not necessary. This would significantly improve the lifetime of the components made of Al, Al—Si, Mg, and Ti alloy, and also reduce the manufacturing cost.

The present invention will be further described with reference to the following examples.

### EXAMPLE 1

As shown in FIG. 1, a rotating hollow shaft 1 with one to four spraying heads 2, which is connected to a high voltage power supply, sprays an electrolytic solution 3 onto an interior surface of an Al—Si cylinder or engine block 4 bore 5. For multiple cylinders or bores, the above spraying head is required for each of cylinders or bores. For a V6 engine which has six cylinder bores, six above systems are usually needed.

When the process starts, the surface of said Al—Si alloy is electrochemically etched first by the alkaline solution. The etched Al matrix surface then grows with the formation of a thin oxide layer produced by plasma oxidation when the applied voltage increases, making the coated surface smoother than the etched surface. The dielectric plasma discharges on the oxide surface also cause a large number of dimples on its surface that can be favorably utilized as reservoirs of oil lubricants for reduction of friction and shear force during tribological applications. The discharge plasma also produces melting zones on Al and Si boundary areas resulting in formation of metallurgical bonds between the Al matrix and Si grains.

For instance, the as-prepared thin coating, of 0.5 to 5 microns in thickness, on the interior surfaces of the engine bores can reduce mild and severe wear problems which may otherwise occur if there is no such coating on them.

### EXAMPLE 2

As shown in FIG. 2, a fixed hollow shaft 1 with one spraying head 2 sprays an electrolytic solution 3 onto the exterior surfaces of an Al—Si piston 6. The oxide coating forms on the exterior surfaces of the piston 7.

For instance, the as-prepared thin coating, of 0.5 to 5 microns in thickness, on the exterior surface of said a piston can reduce a mild and severe wear problem.

### EXAMPLE 3

The oxide coating on an Al—Si alloy and Mg component eliminates metal-to-metal contact in a tribological system. The coating on engine block bores and pistons made of any of the said alloys can withstand a higher heat impact than its bare alloy bores and pistons. Therefore, the oxide coating would reduce the risk of adhesive or scuffing wear. The coated engine block bores also have a thermal conductivity similar to metallic engine bores, which would improve heat dissipation and reduce engine bore distortions. This kind of oxide coating is applied particularly onto engine bores and pistons made of Al and Mg alloys.

### EXAMPLE 4

The thin oxide coating formed on an Al—Si alloy can be applied onto a sleeveless Al engine bore and piston for protection from mild and severe engine wear.

### EXAMPLE 5

The thin oxide coating formed on an Mg alloy can be applied onto a sleeveless Mg engine bore and piston for battling mild and severe engine wear.

### EXAMPLE 6

The as-prepared oxide coating on an Al, Al—Si, Mg or Ti alloy has an enhanced metallurgical and tribological property, and has a smooth surface finish as well as a little dimension change. Post-treatments, polishing, honing, and cross-hatching are not necessary after the coating process. Those characteristics would significantly improve the wear resistance of the coated alloy and also reduce the manufacturing cost.

### EXAMPLE 7

The oxide coating has a high corrosion resistance, thus, the surface coating is used to protect the engine block bores and pistons from corrosion problems caused by alternative fuels, E85 and biodiesel, and coolant.

### EXAMPLE 8

The spraying heads can be held and maneuvered by an automated robotic system for the localized surface treatment on large Al and Mg sheets, extrusions, and cast components as well as on the areas of welding, bolting, riveting, and adhesive bonding. The coated surface has a ceramic layer on the top of the metals, providing protection from general and galvanic corrosion.

What is claimed is:

1. A process of forming an oxide coating with dimples distributing on a surface of a metallic article, the process comprising an electrochemical etching in an electrolytic solution followed by plasma oxidation, said etching and oxidation steps occurred under a high voltage, said oxidation step forming an oxide coating which compensates the dimension change occurred during said etching step, and said plasma oxidation simultaneously generating dimples on the coating surface.

2. The process as claimed in claim 1, wherein the treated article is made of an aluminium alloy including an aluminium-silicon alloy.

3. The process as claimed in claim 1, wherein the treated article is made of a magnesium alloy.

4. The process as claimed in claim 1, wherein the treated article is made of a titanium alloy.

5. The process as claimed in claim 1, wherein the treated article comprises combination of aluminium, aluminium-silicon, magnesium, and titanium alloys connected through casting, welding, bolting, riveting, and adhesive bonding.

6. The process as claimed in claim 1, wherein the etching and oxidation steps operate under an increasing voltage to the voltage in excess of 150 volts.

7. The process as claimed in claim 1, wherein the oxidation step forms an oxide coating with a thickness less than 10 microns which compensates the dimension change of 0.5 to 5 microns occurred during the etching step.

8. The process as claimed in claim 1, wherein the oxide coating surface has more than 5,000 dimples per square millimeter and the dimple size is in a range of 0.5 to 5 microns in diameter.

9. The process as claimed in claim 1, wherein the grain boundaries of hard precipitates on said article surface are metallurgically integrated with the metallic matrix.

10. The process as claimed in claim 1, wherein the treated surface possesses a hardness of 3 to 10 GPa, protecting the soft metallic matrix from scratching and also being compatible to counterface materials.

11. The process as claimed in claim 8, wherein the dimples are favourably utilized as reservoirs of an oil lubricant for reduction of friction and shear force caused by a sliding contact.

12. The process as claimed in claim 9, wherein the metallurgical bonding between hard precipitates and metallic matrix is utilized to avoid breaking and delaminating of the hard precipitates.

13. The process as claimed in claim 1, wherein the treated surface is the surface of an engine block cylinder bore and piston and its arithmetic mean average surface roughness R.sub.a is less than 0.6 micron.

14. The process as claimed in claim 13, wherein the oxide coating formed on an Al—Si alloy is applied onto an Al engine cylinder bore and piston for their protection from mild and severe engine wear.

15. The process as claimed in claim 13, wherein the oxide coating formed on an Mg alloy is applied onto a sleeveless Mg engine bore and piston for their protection from mild and severe engine wear.

16. The process as claimed in claim 1, wherein the oxide coating on the treated surface protects said article from corrosion caused by corrosive environment, alternative fuel, and engine coolant.

17. The process as claimed in claim 16, wherein the coated surface can be a localized surface on a large Al and Mg sheet, extrusion, and cast component.

18. The process as claimed in claim 16, wherein the coated surface can be on the area of welding, bolting, riveting, and adhesive bonding.
